(19) United States
(12) Patent Application Publication
(10) Pub. No.: US 2025/0173557 A1
(43) Pub. Date: May 29, 2025

(54) DEVICES AND METHODS FOR COMPRESSING NEURAL NETWORKS

(71) Applicant: HUAWEI TECHNOLOGIES CO., LTD., Shenzhen (CN)

(72) Inventors: Joseph KAMPEAS, Hod Hasharon (IL); Emir HALEVA, Hod Hasharon (IL); Yury NAHSHAN, Hod Hasharon (IL); Hanoch KREMER, Hod Hasharon (IL)

(21) Appl. No.: 19/038,531

(22) Filed: Jan. 27, 2025

Related U.S. Application Data
(63) Continuation of application No. PCT/EP2022/071324, filed on Jul. 29, 2022.

(51) Int. Cl. G06N 3/0495

(52) U.S. Cl. CPC G06N 3/0495

(57) ABSTRACT

A data processing apparatus for compressing a neural network is disclosed. The apparatus comprises a processing circuitry configured to operate the neural network that comprises a plurality of processing layers. Each processing layer comprises a plurality of neural network weights. The processing circuitry is further configured to compress the neural network by quantizing the plurality of neural network weights of each processing layer using a respective quantization bin size and by encoding the plurality of quantized neural network weights of each processing layer to obtain a compressed neural network. The processing circuitry is further configured to determine, for each processing layer, a norm based on the plurality of neural network weights of each processing layer and to determine the respective quantization bin size for each processing layer based on the norm of the processing layer.

### CROSS-REFERENCE TO RELATED APPLICATIONS

This application is a continuation of International Application PCT/EP2022/071324, filed on Jul. 29, 2022, the disclosure of which is hereby incorporated by reference in its entirety.

### TECHNICAL FIELD

The present disclosure relates to data processing. More specifically, the present disclosure relates to devices and methods for operating and compressing neural networks.

### BACKGROUND

Artificial Neural Networks (ANN), for instance, in the form of convolutional neural networks (CNN) are being implemented in more and more electronic devices for a variety of different purposes, such as image or speech processing. ANNs, however, are usually demanding with respect to computational resources and consume a significant amount of energy, for instance, due to frequent memory accesses by the layers of an ANN and have a large memory footprint. For large ANNs with many neural network weights per layer the memory footprint may become very substantial. Therefore, it is a challenge to implement large ANNs on electronic devices with reduced hardware capabilities in terms of processing power, memory and energy storage, such as smartphones, intelligent cameras or other types of IoT devices. Even in cloud computing, where the processing capabilities, the memory and the power resources of cloud servers are abundant, reducing the memory footprint of ANNs may provide advantages.

To address the issues mentioned above there have been some suggestions to use compression techniques for decreasing the size, i.e., the overall memory footprint of ANNs, typically subject to an error (accuracy) constraint, and obtaining a smaller neural network that is (almost) as capable as the original neural network.

### SUMMARY

It is an object of the present disclosure to provide improved devices and methods for operating and compressing neural networks.

The foregoing and other objects are achieved by the subject matter of the independent claims. Further embodiments are apparent from the dependent claims, the description and the figures.

According to a first aspect, a data processing apparatus for operating and compression a neural network (also referred to as neural network model) is disclosed. The data processing apparatus comprises a processing circuitry configured to operate the neural network, wherein the neural network comprises a plurality of processing layers, wherein each processing layer comprises, i.e. is defined by a plurality of neural network weights. The processing circuitry is further configured to compress the neural network, wherein for compressing the neural network the processing circuitry is configured to quantize the plurality of neural network weights of each processing layer using a respective quantization bin size and to encode the plurality of quantized neural network weights of each processing layer for obtaining a compressed neural network. The processing circuitry is further configured to determine for each processing layer a norm based on the plurality of neural network weights of each processing layer and to determine the respective quantization bin size for each processing layer based on the norm of the respective processing layer.

In an embodiment, the processing circuitry is configured to determine the norm of the respective processing layer based on the plurality of neural network weights of the respective processing layer as the square root of the sum of squares of the plurality of neural network weights of the respective processing layer (also known as L2 norm).

In an embodiment, the processing circuitry is configured to determine the respective quantization bin size for each processing layer based on the norm of the respective processing layer such that the respective quantization bin size is proportional to the norm of the respective processing layer.

In an embodiment, the processing circuitry is configured to determine the respective quantization bin size for each processing layer as a product of the norm of the respective processing layer and a proportionality constant, wherein the proportionality constant is substantially the same for all processing layers.

In an embodiment, the processing circuitry is configured to determine the proportionality constant based on an adjustable target quantization error.

In an embodiment, the processing circuitry is further configured to determine a quantization error (induced by quantizing the plurality of neural network weights of each processing layer using a respective quantization bin size) and to determine the proportionality constant to be the largest proportionality constant or close to the largest proportionality constant, for which the determined quantization error is still smaller than or equal to the target quantization error. The quantization error may be local quantization error per processing layer or a global quantization error produced by all processing layers.

In an embodiment, the processing circuitry is configured to determine the proportionality constant using a giant-step baby-step scheme.

In an embodiment, the processing circuitry is configured to encode the plurality of quantized neural network weights of each processing layer using an entropy encoding scheme, in particular a Huffman encoding scheme, an Arithmetic encoding scheme and/or an Asymmetric Numeral Systems, ANS, encoding scheme.

In an embodiment, the data processing apparatus further comprises a volatile or non-volatile memory, wherein the volatile or non-volatile memory, in particular a RAM is configured to store the compressed neural network, i.e. for each processing layer the plurality of quantized and encoded neural network weights.

In an embodiment, for operating the neural network the processing circuitry is further configured to decompress the compressed neural network layer by layer. For instance, the layer may be loaded from the RAM to a cache memory.

In an embodiment, the processing circuitry is further configured to compress input data of the neural network.

In an embodiment, the plurality of processing layers comprises one or more sparse processing layers.

According to another aspect a computer-implemented data processing method is provided, wherein the method comprises a step of operating a neural network, wherein the neural network comprises a plurality of processing layers, wherein each processing layer comprises a plurality of neural network weights. The method comprises a further step of determining for each processing layer a norm based on the plurality of neural network weights of each processing layer. Moreover, the method comprises a step of determining a respective quantization bin size for each processing layer based on the norm of the respective processing layer. The method comprises a further step of compressing the neural network by quantizing the plurality of neural network weights of each processing layer using a respective quantization bin size and by encoding the plurality of quantized neural network weights of each processing layer for obtaining a compressed neural network.

The data processing method can be performed by the data processing apparatus according to the first aspect. Thus, further features of the data processing method according to the second aspect result directly from the functionality of the data processing apparatus according to the first aspect and its embodiments described above and below.

According to a further aspect a computer program or a computer program product is provided, comprising a computer-readable storage medium carrying program code which causes a computer or a processor to perform the data processing method according to the second aspect when the program code is executed by the computer or the processor.

The different aspects of the present disclosure can be implemented in software and/or hardware.

Details of one or more embodiments are set forth in the accompanying drawings and the description below. Other features, objects, and advantages will be apparent from the description, drawings, and claims.

### BRIEF DESCRIPTION OF THE DRAWINGS

In the following embodiments of the present disclosure are described in more detail with reference to the attached figures and drawings, in which:

FIG. 1 is a schematic diagram illustrating a data processing apparatus according to an embodiment for operating and compressing a neural network;

FIG. 2 is a schematic diagram illustrating an exemplary neural network implemented by the data processing apparatus according to an embodiment;

FIG. 3 is a diagram illustrating a quantization range and a plurality of quantization bins for uniform quantization;

FIG. 4 is a graph illustrating a uniform approximation for an error distribution in a high quantization rate region;

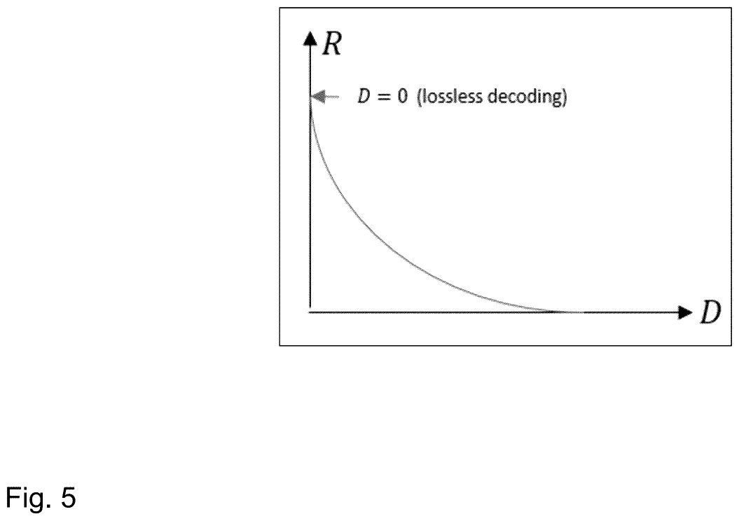

FIG. 5 is a graph illustrating a rate distortion curve;

FIGS. 6a and 6b illustrate a norm-based quantization approach implemented by the data processing apparatus according to an embodiment, where a short weight vector (FIG. 6a) is quantized with smaller quantization bins than a long weight vector (FIG. 6b);

FIG. 7 illustrates a quantization error and a quantization bin size during several iterations of a parameter search implemented by the data processing apparatus according to an embodiment;

FIG. 8 is a schematic diagram illustrating an optimization scheme implemented by the data processing apparatus according to an embodiment;

FIG. 9 is a flow diagram illustrating a hyper parameter search implemented by the data processing apparatus according to an embodiment;

FIG. 10 is a flow diagram illustrating a computer-implemented data processing method according to an embodiment for compressing a neural network;

FIG. 11 is a table illustrating the compression performance provided by the data processing apparatus and method according to an embodiment in comparison with a conventional compressing scheme; and

FIGS. 12a and 12b are diagrams illustrating the compression performance of the data processing apparatus and method according to an embodiment in comparison with a conventional optimization scheme.

In the following identical reference signs refer to identical or at least functionally equivalent features.

### DETAILED DESCRIPTION

In the following description, reference is made to the accompanying figures, which form part of the disclosure, and which show, by way of illustration, specific aspects of embodiments of the present disclosure or specific aspects in which embodiments of the present disclosure may be used. It is understood that embodiments of the present disclosure may be used in other aspects and comprise structural or logical changes not depicted in the figures. The following detailed description, therefore, is not to be taken in a limiting sense, and the scope of the present disclosure is defined by the appended claims.

For instance, it is to be understood that a disclosure in connection with a described method may also hold true for a corresponding device or system configured to perform the method and vice versa. For example, if one or a plurality of specific method steps are described, a corresponding device may include one or a plurality of units, e.g. functional units, to perform the described one or plurality of method steps (e.g. one unit performing the one or plurality of steps, or a plurality of units each performing one or more of the plurality of steps), even if such one or more units are not explicitly described or illustrated in the figures. On the other hand, for example, if a specific apparatus is described based on one or a plurality of units, e.g. functional units, a corresponding method may include one step to perform the functionality of the one or plurality of units (e.g. one step performing the functionality of the one or plurality of units, or a plurality of steps each performing the functionality of one or more of the plurality of units), even if such one or plurality of steps are not explicitly described or illustrated in the figures. Further, it is understood that the features of the various exemplary embodiments and/or aspects described herein may be combined with each other, unless specifically noted otherwise.

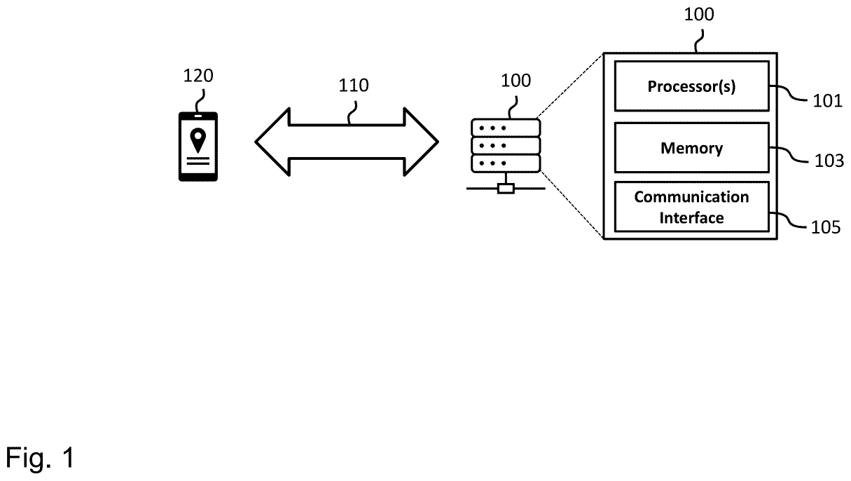

FIG. 1 is schematic diagram illustrating a data processing apparatus 100 according to an embodiment. In the embodiment shown in FIG. 1 the data processing apparatus 100 is, by way of example, a server 100, for instance, a cloud server 100. As will be appreciated, however, in other embodiments the data processing apparatus 100 may be implemented, for instance, as a server farm, a desktop computer, a laptop computer, a tablet computer, a smartphone or another device having the computational resources for implementing a neural network.

As illustrated in FIG. 1, the server 100 may comprise a processing circuitry 101, such as one or more processors or cores 101 for processing data and a memory 103 for storing and retrieving data. Furthermore, the server 100 may comprise a communication interface 105, including, for instance, for exchanging data with other devices, such as a smartphone 120, via a wired and/or wireless communication channel 110.

The processing circuitry 101 of the server 100 may be implemented in hardware and/or software. The hardware may comprise digital circuitry, or both analog and digital circuitry. Digital circuitry may comprise components such as application-specific integrated circuits (ASICs), field-programmable arrays (FPGAs), digital signal processors (DSPs), or general-purpose processors. The memory 103 may store executable program code which, when executed by the processing circuitry 101, causes the server 100 to perform the functions and methods described herein.

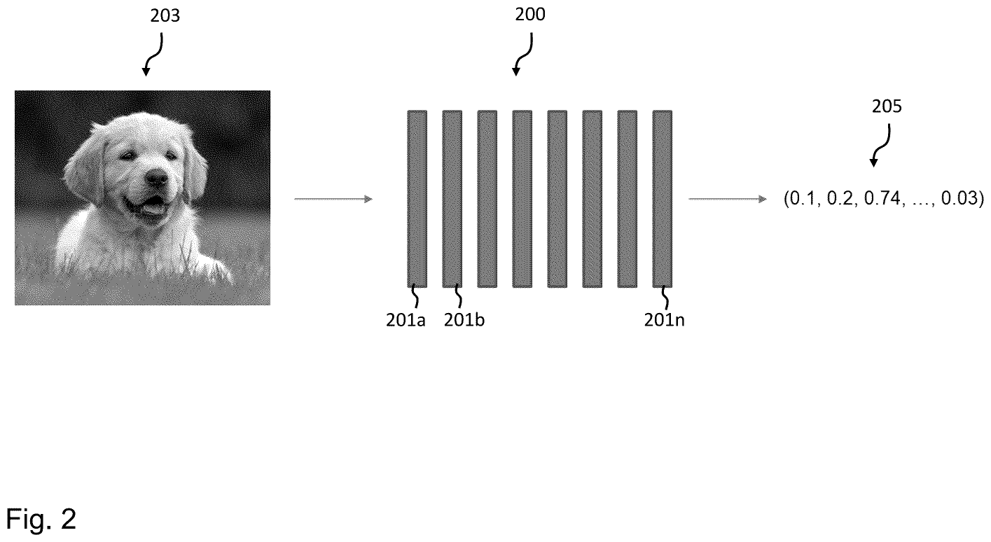

As will be described in more detail in the following under further reference to FIG. 2, the processing circuitry 101 of the data processing apparatus 100, e.g. server 100 is configured to implement, i.e. operate a neural network 200, which comprises a plurality of processing layers 201a-n. Each processing layer 201a-n comprises plurality of neural network weights, which are usually determined or adapted during a training phase of the neural network 200. The plurality of neural network weights of each processing layer 201a-n may be stored in the memory 103 of the data processing apparatus 100. The plurality of processing layers 201a-n may comprise any type of neural network layer defined by a plurality of neural network weights, such as fully connected, convolution, deconvolution, recurrent layers and the like. By way of example, in the embodiment shown in FIG. 2 the plurality of processing layers 201a-n of the neural network 200 implemented by the data processing apparatus 100 are configured to generate output data 205 in the form of a feature vector 205 based on input data 203 in the form of an input image 203.

Before describing in more detailed embodiments of the data processing apparatus 100 for compressing the plurality of processing layers, some further technical background will be introduced in the following.

Compression of data generally consists of two phases, namely quantization and encoding. In the quantization phase, the number of unique values (symbols) is reduced. As the number of unique symbols gets smaller, so does the entropy and consequently so does the number of bits required for representation of the layer. This may be an issue when handling neural networks, since each processing layer may have a different number of parameters, i.e. neural network weights, and may follow a different distribution, which carries a different entropy. Generally, it may be beneficial to quantize each layer at a rate that maintains proximity with respect to the original layer distribution. Still, representing the original layers' symbols at a rate that is lower than their original entropy introduces distortion (i.e., quantization error). Finding a solution that quantize the model at the lowest possible bit-rate while satisfying a certain quantization error (distortion) requirement (i.e. a target quantization error threshold) is at the heart of quantization optimization problems, and is known as the rate-distortion problem. Further, a compression scheme that quantize each layer at a different rate is referred to as a mixed-bit solution compression scheme.

In the encoding phase, the symbols statistics are gathered, and the quantized weights are compressed with an asymptotically optimal entropy compressor (e.g., Huffman, arithmetic encoding, ANS, and the like), which sets for each symbol a length that is inversely proportional to its probability. Besides reducing the number of symbols, the quantization may have an extensive effect on the compression since it produces a unique symbol statistics (distribution), and hence, entropy. Thus, different quantization schemes may lead to different entropy values even when the quantization rates are practically the same. Generally, an entropy encoder compresses these quantized values to their entropy limit without introducing further errors (i.e., lossless coding). Accordingly, for optimizing the compression of a neural network, the objective is choosing the quantization parameters that achieve the largest compression ratio while satisfying the quantization error constraint.

In a typical setting, optimization of the quantization parameters requires finding for each processing layer a quantization range ([min, max]) and a number of quantization levels N (or equivalently, a quantization rate R=log₂(N), from which the quantization error (distortion) is measured over each layer separately). This per layer distortion approach is simpler and can be analyzed with the standard rate-distortion theory. Nonetheless, it misses the true purpose of the optimization by focusing on each layer independently, instead of focusing on the whole neural network. Moreover, such compression schemes ignore the propagating error effect that spreads the distortion to the consecutive layers in addition to their own quantization error. Addressing this error propagation is complex, as the parameters optimization search-space in the quantization process gets exponentially large with the number of processing layers of the neural networks. This makes an exhaustive search practically impossible even for moderate size neural networks.

As already mentioned above, the goal of quantization is reducing the number of symbols before the (lossless) compression. It has been shown that uniform scalar quantization is (asymptotically) optimal when one intends to further compress the quantized data. In other words, non-uniform scalar quantization techniques do not yield better compression than the simple uniform scalar quantization. This is since uniform quantization maintains the probabilistic characteristics of the weights, and hence, facilitates reaching (asymptotically) the entropy limit.

For a variable

$$W ∈ [ - \frac{A}{2} , \frac{A}{2} ]$$

a scalar uniform quantizer q_{U}(W) with N quantization intervals (i.e., quantization bins) partitions the interval

$$[ - \frac{A}{2} , \frac{A}{2} ]$$

uniformly, such that the partition boundaries are in

$$\{ - \frac{A}{2} + k \frac{A}{N} , k = 0 , … , N \}$$

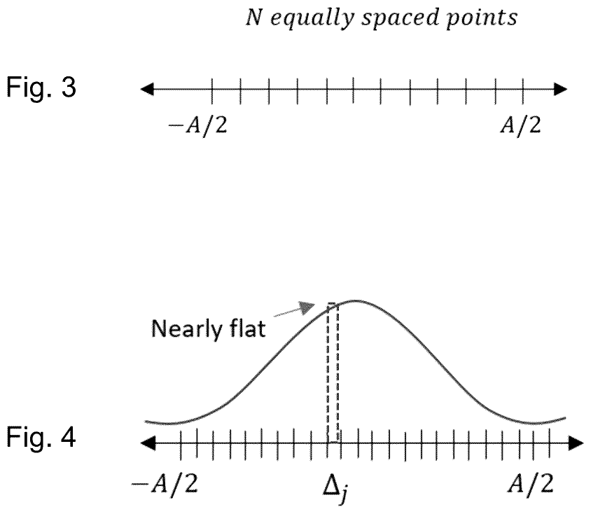

(as illustrated in FIG. 3). Then, any realization of W that falls in quantization bin j is represented by the index j, whose reconstruction value cⱼ is typically the value of W at the middle of that quantization bin. The fidelity of this quantization is typically measured by a distortion measure, for example, the Mean Squared Error (MSE) criterion, defined as follows:

$$D ( N ) = E {\vert W - {q}_{U} ( W ) \vert}^{2}$$

Often, it is more convenient to analyze the uniform quantizer in terms of the quantization rate R=log₂ N instead of the number of quantization bins N. This rate R essentially depicts the number of bits required to index the quantization bins. To analyze this quantizer, a high-rate regime (R>>1) is considered, where the probability curve in each quantization bin Δⱼ is nearly flat, as illustrated in FIG. 2. That is, conditioning on Δⱼ, the quantization error distribution is approximately uniform. Thus, let cⱼ and Δⱼ be the j-th quantization (reconstruction) point and quantization interval, respectively. The relation between the quantization interval and the resulting quantization MSE is the following relation (1):

$$E {\vert W - {q}_{U} ( W ) \vert}^{2} = {\sum }_{j = 1}^{N} E [ {\vert W - {c}_{j} \vert}^{2} \vert W ∈ {Δ}_{j} ] P ( W ∈ {Δ}_{j} ) \qquad ( 1 )$$

$$( for R ≫ 1 ) \approx {\sum }_{j = 1}^{N} \frac{{\vert {Δ}_{j} \vert}^{2}}{12} P ( W ∈ {Δ}_{j} )$$

$$( {Δ}_{j} = Δ ∀ j ) = \frac{\vert {Δ}^{2} \vert}{12} = \frac{{A}^{2} / {N}^{2}}{12} = \frac{{( max - min )}^{2}}{12} {2}^{- 2 R}$$

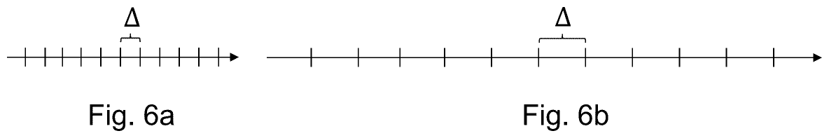

This relation between the quantization rate and its induced distortion is well-known. In an embodiment, quantizing at a lower rate R induces larger distortion, and vice versa, given a lower distortion requires a higher rate R. This behavior is illustrated in FIG. 5 and is known as the rate-distortion curve.

As already described above, after quantizing the neural network weights, they are being compressed with entropy encoders. For completeness, in the following a short background on entropy achieving compression schemes is provided.

An optimal compression scheme allocates to each symbol a bit-length that is inversely proportional to its probability. That is, common symbols are represented by fewer bits than rare ones. The difference between entropy encoders inherent in their apparatus that captures the dependencies between the symbols. A practical perspective is to consider those as finite002Dstate automata. In this sense, Huffman coding is the simplest and fastest encoder which utilizes a single state. That is, for every input alphabet symbol, the encoder outputs the corresponding prefix-free code from a lookup-table. Nevertheless, Huffman coding must allocate an integer number of bits per symbol, and hence, can get quite far from the entropy limit that allows a fractional number of bits per symbol.

Arithmetic coding may improve this drawback of Huffman coding, allowing fractional number of bits per symbol, and hence is asymptotically optimal. Yet, in terms of number of states, arithmetic coding may get exponentially large, as it counts all previous symbols to code the next one. This involves a lot of arithmetic, which may make the implementation cumbersome in terms of memory and latency.

J. Duda, “Asymmetric numeral systems,” arXiv preprint arXiv:0902.0271, 2009 suggested an encoding scheme that is based on Asymmetric Numeral Systems (ANS), which bridges between Huffman coding and Arithmetic coding. That is, it provides lossless compression at a very high compression and decompression speeds. In terms of finite-state size, it facilitates configuring the encoding table size. Further, it utilizes simple arithmetic (only shifts and additions) which has efficient hardware implementations.

Embodiments disclosed herein make use of the finding that rotations are induced by the linear operations defined by the plurality of processing layers 201a-n of the neural network 200. These rotations make the compression optimization intricate, as it affects the quantization parameters of successive processing layers 201a-n. For a mixed-bit scheme, typical quantization requires finding for each processing layer i: (a) the quantization range [min, max]ᵢ and (b) quantization rate Rᵢ (an integer). From these, the conventional width of the quantization is given by the following equation (2):

$${Δ}_{i} = \frac{{( max - min )}_{i}}{{2}^{{R}_{i}} - 1} \qquad ( 2 )$$

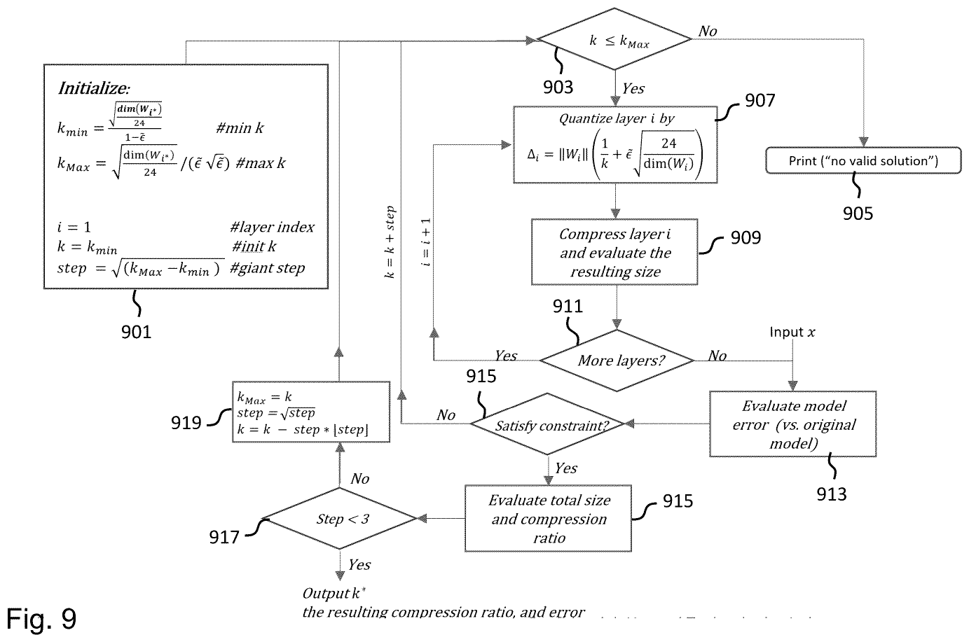

Yet, the quantization range is sensitive to rotations. Geometrically, each processing layer 201a-n may have its own orientation (direction), length and dimension. The neural network weights of each processing layer 201a-n get rotated (and stretched) by its input, and the output of this layer rotates the successive layer's weights, and so on and so forth. The series of rotations between layers determines the models' output, and hence it's performance (as will be explained in more detail in the context of FIG. 8 further below). Moreover, the quantization should be appropriate to all the rotations in the (calibration) data. This is intricate, as each input in the data rotates the layer differently, and the quantization should satisfy all these rotations.

To illustrate how rotations affect the quantization range, a simple example is provided with the plurality of weights of a layer expressed as a weight vector \vec{w}=(1,0). Thus, in this case max−min=1 and the resulting bin width=(max−min)/(2^{R}−1)=1/255 in the case of 8 bit quantization. However, after a rotation of 45° in the counter clockwise direction, the resulting weight vector is

$$( \frac{1}{\sqrt{2}} , \frac{1}{\sqrt{2}} ) ,$$

and one obtains max−min=0, as well as bin width=0. Consequently, the conventional methodology yields a different quantization based on the exact rotation of the weights.

Moreover, using a conventional quantization may induce a quantization error requirement that is too small. In an embodiment, in the following it will be shown based on equations (1) and (2) that the induced quantization error in the cosine-similarity case is

$${ϵ}_{i} = \frac{\vert {dim}_{i} \vert}{{‖ {W}_{i} ‖}^{2}} \frac{{( max - min )}_{i}^{2}}{( {N}_{i}^{2} - 1 ) 24} ,$$

which scales as order of O(|dimᵢ|/∥Wᵢ∥²). For the relative-error, the resulting quantization error is

$${ϵ}_{i} = \sqrt{\vert {dim}_{i} \vert \frac{{( max - min )}_{i}^{2}}{( {N}_{i}^{2} - 1 ) \cdot 12 {‖ {W}_{i} ‖}^{2}}} .$$

The error becomes smaller as the weights' norm increases, which may be too restrictive, and hence, will induce fine quantization that translates to a poor compression ratio. Another drawback of the conventional schemes is focusing on quantization processes that produce an integer number of bits. This is typically not optimal in terms of compression, as other representations that were quantized at a fractional rate may further reduce the resulting entropy and thus, attain a higher compression ratio.

Considering the scenario where the layer weights are sparse (i.e., many weight values are inherently zeros) making use of compressed formats such as compressed sparse row (CSR) speeds up the computation since mathematical operations that involve zeros may be skipped. However, memory-wise the CSR format is not optimal in general as it allocates memory for both values and their indices without encoding them at all. Combining the embodiments disclosed herein with weight sparsity may yield remarkable compression ratios.

Another disadvantage of conventional compression schemes is the optimization time/complexity that is required to find a suitable solution. That is, in many prior art approaches the parameterization must be tuned during the network training. Other, post-training methods perform layer-by-layer optimization which are typically cumbersome and require dedicated hardware (e.g., GPUs).

As already described above, the data processing apparatus 100 shown in FIG. 1 is configured to operate and compress, for instance, the plurality of processing layers 201a-n of the neural network 200 shown in FIG. 1, wherein each processing layer 201a-n comprises, i.e. is defined by a plurality of neural network weights. The processing circuitry 101 of the data processing apparatus 100 is configured to compress the neural network 200, wherein for compressing the neural network 200 the processing circuitry 101 of the data processing apparatus 100 is configured to quantize the plurality of neural network weights of each processing layer 201a-n using a respective quantization bin size and to encode the plurality of quantized neural network weights of each processing layer 201a-n for obtaining a compressed neural network.

The processing circuitry 101 of the data processing apparatus 100 is further configured to determine, i.e. compute for each processing layer 201a-n a norm based on the plurality of neural network weights of each processing layer 201a-n and to determine the respective quantization bin size for each processing layer 201a-n based on the calculated norm of the respective processing layer 201a-n.

For the optimization, embodiments disclosed herein focus on error constraints at the output 205 of the neural network 200. This is manifestly different from the conventional approach, since the local quantization errors in each processing layer 201a-n contribute differently to the resulting error at the output 205 of the neural network 200, and the standard rate-distortion theory may not hold directly for this case. Embodiments disclosed herein address the quantization parameters optimization by formulating the optimization problem at hand into a single parameter optimization, which allows entangling the plurality of processing layers 201a-n of the neural network 200. Deriving bounds on this single parameter search-space and using a nested giant-step baby-step approach, as implemented by embodiments of the data processing apparatus 100, makes the parameter search extremely efficient and fast.

Embodiments of the data processing apparatus 100 implement a mixed-bit fractional quantization scheme that allows for an efficient search over the generalized rate-distortion curve. Embodiments disclosed herein perform a rotation invariant quantization that is both scalable (with the number of processing layers 201a-n) and extremely fast. The embodiments disclosed herein may be extended to a full-quantization, where the data processing apparatus 100 is configured to compress both the neural network weights of the plurality of processing layers 201a-n as well as the input data (also referred to as activations). Moreover, embodiments disclosed herein provide improved compression results for a neural network 200 including one or more sparse processing layers 201a-n, because the abundance of zero weight values makes the network highly compressible.

Embodiments of the data processing apparatus 100 disclosed herein allow maximizing the neural network compression ratio subject to an error constraint at the output 205 of the neural network 200. This may be regarded as a generalized rate-distortion problem, as the distortion requirement is at the output 205 of the neural network 200. Moreover, embodiments disclosed herein provide a mixed-bit solution, where the i-th processing layer, i.e. one of the processing layers 201a-n gets quantized with a rate Rᵢ bits. Embodiments disclosed herein allow efficiently addressing the exponentially large parameter search space which scales with the number of processing layers 201a-n. Furthermore, embodiments disclosed herein allow finding a parameter solution as fast as possible for meeting time constraints (i.e., few minutes or less).

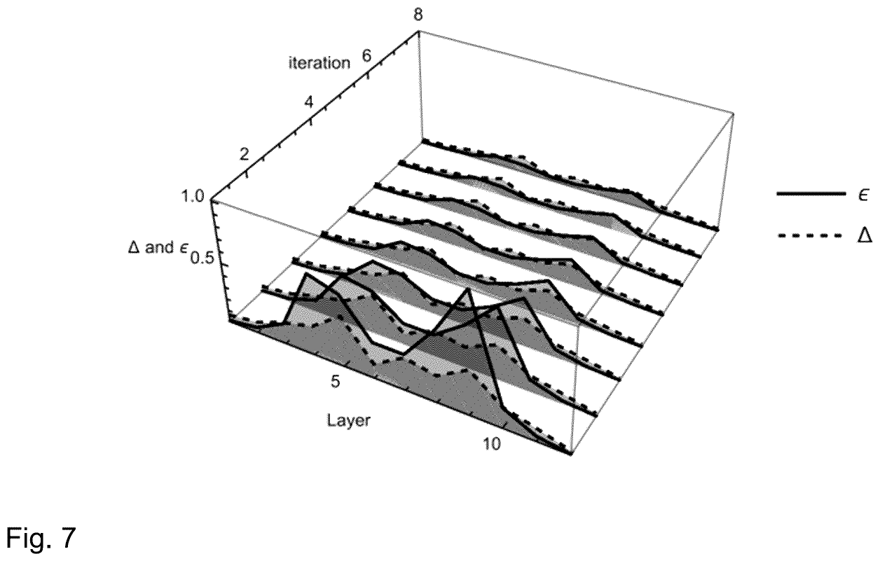

As already described above, the processing circuitry 101 of the data processing apparatus 100 is configured to quantize each processing layer 201a-n of the neural network 200 based on its norm, in particular its L2 norm (which can be regarded as a measure of the size or length of the respective processing layer 201a-n). This approach is based on the finding that the norm, e.g. length of a respective processing layer 201a-n is invariant to rotations. In an embodiment, for the i-th processing layer, i.e. one of the processing layers 201a-n the processing circuitry 101 of the data processing apparatus 100 is configured to choose the quantization bin size Δᵢ∝∥Wᵢ∥ as large as possible. As already mentioned, a larger quantization bin size Δᵢ leads to a larger entropy gain, and hence, a higher compression ratio. As will be appreciated and schematically illustrated in FIGS. 6a and 6b, the approach implemented by the processing circuitry 101 of the data processing apparatus 100 to quantize each processing layer 201a-n of the neural network 200 based on its norm results in a smaller quantization bin size for shorter norms. Consequently, larger processing layers 201a-n (i.e. processing layers 201a-n having a larger norm) get compressed at a higher ratio, and thus, are more significant to the resulting compressed size. Their local quantization error, on the other hand, is also larger, and this tradeoff is addressed by further embodiments of the data processing apparatus 100 described in more detail further below.

As will be appreciated, as a result of the approach implemented by the processing circuitry 101 of the data processing apparatus 100 to quantize each processing layer 201a-n of the neural network 200 based on its norm, the quantization rate essentially used by the data processing apparatus 100 is not restricted to the conventional integer rates. This allows considering non-integer quantization rates that are more compressible.

Since the error constraint is imposed at the output 205 of the neural network 200 and the quantization error of each individual processing layer 201a-n contributes to this global output error, embodiments of the data processing apparatus 100 implement a parameter search that utilizes a single parameter to set the local target error E; and its corresponding quantization bin size Δᵢ for each processing layer 201a-n, instead of the conventional approach of optimizing the quantization range (max−min)ᵢ and the quantization rate Rᵢ parameters. As already mentioned, it may be beneficial to set the local target error ϵᵢ as large as possible to obtain a higher compression ratio. In an embodiment, the processing circuitry 101 of the data processing apparatus 100 may be configured to set the local quantization error ϵᵢ in the order of O(|dim(Wᵢ)|), which is larger by a factor of ∥Wᵢ∥ than the typical quantization error in the cosine distance and the relative error distortion metric.

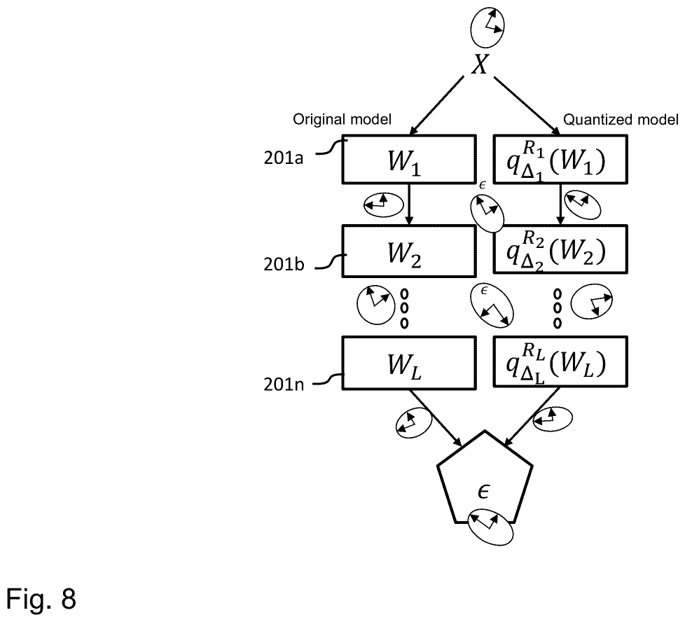

Instead of optimizing layer by layer, as conventionally suggested, for finding the optimal quantization bin size Δᵢ for each processing layer 201a-n in a fast way, the processing circuitry 101 of an embodiment of the data processing apparatus 100 is configured to scale the quantization bin size Δᵢ in all processing layers 201a-n together during the search by using a single optimization parameter. Thus, embodiments disclosed herein maintain the bin width in each layer proportional to its norm, and thus, the proportions between the “errors per layer” are similar throughout the optimization process, as can be seen in FIG. 7. In other words, in an embodiment, the processing circuitry 101 of the data processing apparatus 100 is configured to determine the respective quantization bin size for each processing layer 201a-n based on the norm of the processing layer 201a-n such that the respective quantization bin size is linearly proportional to the norm of the processing layer 201a-n. For instance, the processing circuitry 101 of the data processing apparatus 100 is configured to determine the respective quantization bin size for each processing layer 201a-n as a product of the norm of the processing layer 201a-n and a proportionality constant, wherein the proportionality constant is the same for all processing layers 201a-n and is the single optimization parameter determining the quantization bin size of all processing layers 201a-n.

Even with a single optimization parameter, e.g. the proportionality constant between the norm of each layer 201a-n and its quantization bin size, the search space may be quite large. To address this and make this computationally more feasible, in an embodiment, the processing circuitry 101 of the data processing apparatus 100 is configured to determine and/or set an upper and a lower bound for the parameter search-space and to implement a fast converging “giant-step baby-step” search scheme approach, which allows finding the optimized single parameter, e.g. proportionality constant in O(\sqrt{|Ω|}) steps where |Ω| is the search space size. An exemplary search is illustrated in FIG. 7, which shows values for the quantization error E (solid lines) and the quantization bin size Δ (dashed lines) assigned during the search in each layer per iteration for an exemplary neural network 200 with 12 layers. As can be appreciated from FIG. 7, the proportion of Δ and ϵ between layers, i.e., Δᵢ/Δⱼ and ϵᵢ/ϵⱼ, remain the same throughout the optimization process.

From a system point-of-view, given a pretrained neural network 200 with neural network weight tensors {Wᵢ}, embodiments of the data processing apparatus 100 allow obtaining the smallest (quantized and compressed) version of this neural network 200, which attains an output that is as close as possible to the output 205 of the original, i.e. non-compressed neural network 200. To assess the fidelity of the quantized neural network, an input X may be sent through the original neural network 200 and in parallel through the quantized neural network, as illustrated in FIG. 8, and the distance, i.e. difference between the final outputs is measured. As will be appreciated, the input X may be regarded as calibration data or a random tensor realization.

As the input X propagates through the original neural network 200 and the quantized version thereof, the input X can be regarded to be rotated and maybe stretched by each processing layer 201a-n. When the quantized and the original layers' weights have a similar length (norm), the quantization errors are essentially reflected in rotation shifts, occurring in each of the quantized layers. That is, each quantized layer produces a rotation error into its output, and this error keeps propagating and accumulating over the layers until it reaches the output of the quantized neural network. Note that these rotation shifts may be constructive, and hence, increase the distance, or destructive, and hence, decrease the distance in each layer, with respect to the processing layers 201a-n of the original neural network 200.

In case the output error is sufficiently small (i.e., below a pre-defined threshold), the processing circuitry 101 of the data processing apparatus 100 in an embodiment is configured to compress the neural network 200 layer-by-layer, using, for instance, an asymptotically optimal encoder, such as the ANS. According to rate-distortion theory the average length of a symbol in the i-th processing layer 201a-n after compression is given by the following equation (3):

$$H ( {q}_{{Δ}_{i}}^{{R}_{i}} ( {W}_{i} ) ) = H ( {W}_{i} ) - log ( {Δ}_{i} ) [ bits / symbol ] , \qquad ( 3 )$$

where H(⋅) is the entropy function H(X)=−Σ_{x∈X}pₓ log pₓ. In other words, the quantization reduces the entropy by −log(Δᵢ), thus, a larger quantization bin size Δᵢ yields a larger entropy gain (and, thus, a larger compression). Therefore, in an embodiment, the processing circuitry 101 of the data processing apparatus 100 is configured to determine a quantized version of the neural network 200 that satisfies the target quantization error requirement, while providing the largest possible quantization bin size Δᵢ.

As already described above, conventional quantization parameter optimization involves usually optimizing the quantization range [max, min]ᵢ, and quantization rate Rᵢ for each layer. Even though optimizing the range and rate is a good strategy for quantizing a single layer, where distortion is measured locally, it gets extremely hard to optimize when considering the whole neural network 200 and its distortion at the output 205, as already described above.

Before describing further embodiments of the data processing apparatus 100, in the following the conventional scalar uniform quantizer is revisited, and in particular, the connection of the quantization bin size Δ to the resulting quantization error. From equation (1) above and the law of large numbers one will appreciate that the following relations hold:

$$E [ {\vert W - {q}_{U} ( W ) \vert}^{2} ] = \frac{1}{dim ( W )} {\sum }_{d = 1}^{dim ( W )} {\vert W - q ( W ) \vert}^{2} \approx \frac{1}{dim ( W )} {‖ W - q ( W ) ‖}^{2} \approx \frac{{Δ}^{2}}{12}$$

Based on this mean square error (MSE) other error criteria may be determined.

For example, the relative error criterion (Mean absolute percentage error) may be obtained by taking a square-root and normalizing by the layer norm in the following way:

$${ϵ}_{rel} {=}^{def} \frac{‖ W - q ( W ) ‖}{‖ W ‖} \approx \sqrt{dim ( W ) \frac{{Δ}_{rel}^{2}}{12 {‖ W ‖}^{2}}}$$

Or, in terms of Δᵣₑₗ:

$${Δ}_{rel} \approx {ϵ}_{rel} ‖ W ‖ \sqrt{\frac{12}{dim ( W )}}$$

A cosine distance criterion may be derived based on the finding that the cosine distance is equivalent to the Euclidean distance of normalized vectors up to a constant. Thus, assuming that the norms ∥q(W)∥≈∥W∥ are about the same, the following relation holds:

$${‖ W - q ( W ) ‖}^{2} \approx 2 {‖ W ‖}^{2} ( 1 - cos ( {∠}_{W , q ( W )} ) )$$

Consequently, the following equation (4) holds:

$${ϵ}_{cos} {=}^{def} 1 - cos ( {∠}_{W , q ( W )} ) \approx \frac{‖ W - q ( W ) ‖}{2 {‖ W ‖}^{2}} \approx dim ( W ) \frac{{Δ}_{cos}^{2}}{24 {‖ W ‖}^{2}} \qquad ( 4 )$$

Or, in terms of Δ_{cos} the following relation (5):

$${Δ}_{cos} \approx \sqrt{{ϵ}_{cos}} ‖ W ‖ \sqrt{\frac{24}{dim ( W )}} \qquad ( 5 )$$

In the following, by way of example, the cosine distance analysis will be described in more detail. Based on equations (4) and (5) above it may be appreciated that the quantization bin size Δ can be selected so that it is proportional to the norm ∥W∥ by letting the local quantization errors scale with dim (W). In an embodiment, setting

$$\sqrt{{ϵ}_{cos} ( k )} = \frac{1}{k} \sqrt{\frac{dim ( W )}{24}} ,$$

where k is the parameter to be optimized. Yet, as k gets larger the local errors get smaller, which yields small quantization bin sizes Δ that may be bad for compression. Thus, to enforce quantization and a quantization error, in particular, a small fixed constant \tilde{ϵ} may be added. That is,

$$\sqrt{{ϵ}_{cos} ( k )} = \frac{1}{k} \sqrt{\frac{dim ( W )}{24}} + \tilde{ϵ}$$

The corresponding quantization bin size is:

$${Δ}_{cos} = ‖ W ‖ ( \frac{1}{k} ϵ \sqrt{\frac{24}{dim ( W )}} )$$

The resulting fractional quantization rate for the i-th processing layer 201a-n may be expressed by the following equation (6):

$${R}_{i} = {log}_{2} ( \frac{( max - min )}{{Δ}_{i}} ) = {log}_{2} ( \frac{( max - min )}{‖ {W}_{i} ‖ ( \frac{1}{k} + \tilde{ϵ} \sqrt{\frac{24}{dim ( {W}_{i} )}} )} ) [ bits / symbol ] \qquad ( 6 )$$

This fractional rate Rᵢ is induced by the largest Δᵢ possible, which is substantial for compression. However, practically, after decoding the symbols, they may be stored using one of the nominal representations (e.g., fp32, fp16, int8, and the like).

Based on equation (6) the following entropy gain may be obtained:

$$- {log}_{2} ( {Δ}_{i} ) = - {log}_{2} ‖ {W}_{i} ‖ - {log}_{2} ( \frac{1}{k} + \tilde{ϵ} \sqrt{\frac{24}{dim ( {W}_{i} )}} )$$

As will be appreciated, since the norm of a layer is invariant to rotations, setting a quantization bin size Δ that scales in the same way as the norm, yields a rotation invariant quantization. In other words, the quantization fidelity is independent of the layer's input as it rotates the layer's weights. As will be further appreciated, choosing a different k and, thus, a different proportionality constant for each layer 201a-n would break this rotation invariance.

As already described above, the search and optimization scheme implemented by the processing circuitry 101 of the data processing apparatus 100 according to an embodiment essentially entangles all processing layers 201a-n by using a single parameter, such as the parameter k. Still, the search space Ω(k) can get quite large. In other words, finding the optimal k* that satisfies the error constraint of the compression of the neural network 200 may still be hard. To search the optimal k*, the processing circuitry 101 of the data processing apparatus 100 according to an embodiment is configured to limit the actual search range for the optimal parameter. In the case of cosine distance, an upper bound of the search range may be determined by the processing circuitry 101 of the data processing apparatus 100 in the following way based on the following relation:

$$\sqrt{{ϵ}_{i}} = \frac{1}{k} \sqrt{\frac{dim ( W )}{24}} + \tilde{ϵ} \leq \frac{1}{k} \sqrt{\frac{dim ( {W}_{{i}^{*}} )}{24}} + \tilde{ϵ} ,$$

where i* is the index of the largest layer (i.e. the layer with the largest norm) of the neural network 200. As will be appreciated, in the search scheme implemented by the processing circuitry 101 of the data processing apparatus 100 this is the processing layer 201a-n whose error converges to \tilde{ϵ} last. This can be used for defining, where to stop the search. In an embodiment, for a sufficiently large k, the error is approximately \sqrt{ϵ_{i*}}=\tilde{ϵ}+o(\tilde{ϵ}). At this point, the error converges even at the largest layer (and hence, for the rest of layers as well, which have a smaller norm).

Namely,

$$\frac{1}{k} \sqrt{\frac{dim ( {W}_{{i}^{*}} )}{24}} + \tilde{ϵ} \to o ( \tilde{ϵ} ) + \tilde{ϵ}$$

which happens when

$$k \geq \frac{\sqrt{\frac{dim ( {W}_{{i}^{*}} )}{24}}}{\tilde{ϵ} \sqrt{\tilde{ϵ}}} .$$

For an exemplary value of \tilde{ϵ}=0.01, the upper limit is

$$k \leq 1000 \sqrt{\frac{dim ( {W}_{{i}^{*}} )}{24}} .$$

For a lower bound of the search range, the fact may be exploited that ϵᵢ≤1 in the cosine distance criterion. Thus, focusing on the largest layer i* again, it may be observed that

$$\frac{1}{k} \sqrt{\frac{dim ( {W}_{{i}^{*}} )}{24}} + \tilde{ϵ} \leq 1$$

which happens when

$$k \geq \sqrt{\frac{dim ( {W}_{{i}^{*}} )}{24}} / ( 1 - \tilde{ϵ} ) .$$

Thus, in an embodiment, the processing circuitry 101 of the data processing apparatus 100 may be configured to limit the search to the following range:

$$\frac{\sqrt{\frac{dim ( {W}_{{i}^{*}} )}{24}}}{1 - \tilde{ϵ}} \leq k \leq \sqrt{\frac{dim ( {W}_{{i}^{*}} )}{24}} / ( \tilde{ϵ} \sqrt{\tilde{ϵ}} ) .$$

For further improving the search time the processing circuitry 101 of the data processing apparatus 100 may be further configured to implement a nested giant-step baby-step search approach that will be described in more detail in the following.

At the beginning, the “giant-step” stage, only \sqrt{|Ω(k)|} values of k are evaluated. The smallest k that suffice in terms of output error then becomes the new upper limit, and the search region is refined with a smaller region of k that has, again, only \sqrt{|Ω(k)|} values to inspect. This continues repeatedly, until the search step is sufficiently small. This allows finding a good solution in relatively few iterations (e.g. less than 40 iterations).

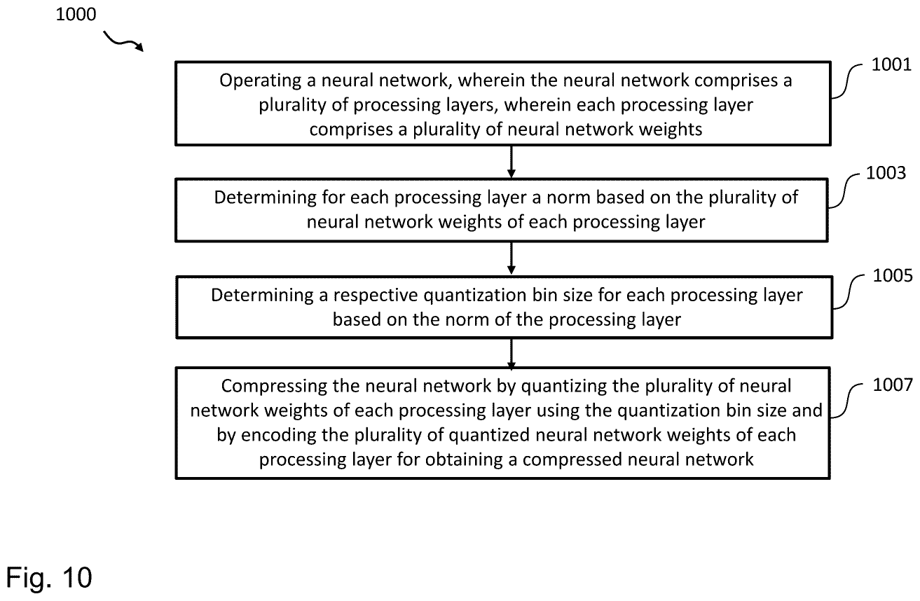

More details of the nested giant-step baby-step search approach implemented by the processing circuitry 101 of the data processing apparatus 100 are illustrated in the flow diagram shown in FIG. 9. Initially, the search range and the initial step size is set to be the square root of the searching range size (see 901 of FIG. 9). This step size is refined repeatedly until the best solution is found (see 917 and 919 of FIG. 9). In iteration k as long as k is not larger than kₘₐₓ (see 903, 905 of FIG. 9), each layer i is quantized with respect to its norm, using the following quantization bin size (see 907, 909, 911 of FIG. 9):

$${Δ}_{i} = ‖ {W}_{i} ‖ ( \frac{1}{k} + \tilde{ϵ} \sqrt{\frac{24}{dim ( {W}_{i} )}} )$$

This induces a smaller entropy to this layer that can be attained by compression. Then, to evaluate the distortion at the output, the model is fed with calibration (or random) data (see 913 of FIG. 9), and the cosine distance is measured at the output. In case the resulting model does not satisfy the error requirement (see 915 of FIG. 9), the k parameter is increased by the step size and the model is quantized again at a higher rate (i.e., finer quantization). Otherwise, the compression ratio is stored, and the search continues in a smaller search range, using smaller search step (see 919 of FIG. 9). The latter repeats until the search step is sufficiently small (see 917 of FIG. 9). Essentially, this search scheme implemented by the processing circuitry 101 of the data processing apparatus 100 according to an embodiment strives to find a solution with the smallest possible k. As mentioned, since the rate distortion curve is monotonously decreasing, the smallest k that satisfies the target quantization error requirement yields the largest compression ratio.

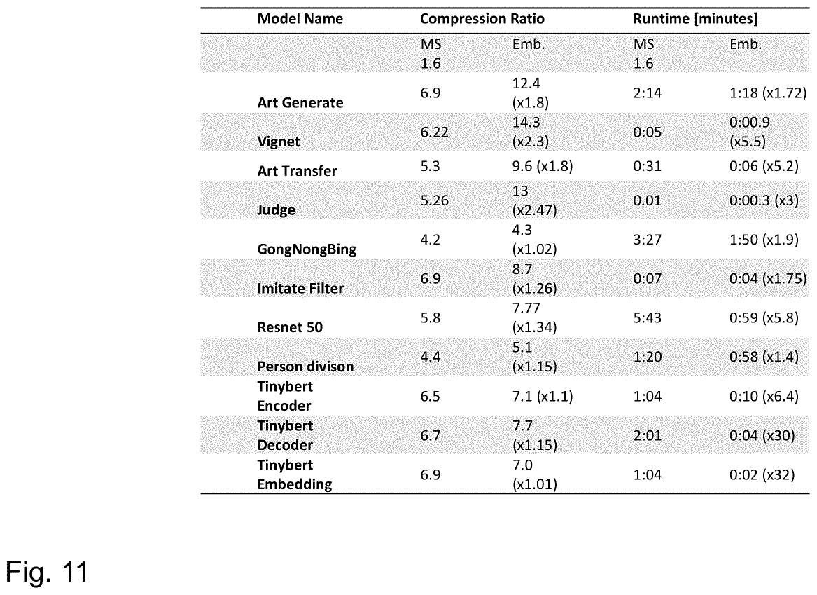

FIG. 10 is a flow diagram illustrating an embodiment of a computer-implemented method 1000 for operating and compressing a neural network, such as the neural network 200 schematically illustrated in FIG. 2. The method 1000 comprises block 1001 of operating the neural network 200, wherein, as already described above, the neural network 200 comprises the plurality of processing layers 201a-n and wherein each processing layer 201a-n comprises a plurality of neural network weights. Moreover, the method 1000 comprises block 1003 of determining for each processing layer 201a-n the norm of the layer based on the plurality of neural network weights of each processing layer 201a-n. The method 1000 further comprises block 1005 of determining the respective quantization bin size for each processing layer 201a-n based on the norm of the processing layer 201a-n. As described above, in an embodiment, this is done in such a way that the total error of the neural network output 205 is smaller than the desired target error. Moreover, the method 1000 comprises block 1007 of compressing the neural network 200 by quantizing the plurality of neural network weights of each processing layer 201a-n using the quantization bin size and by encoding the plurality of quantized neural network weights of each processing layer 201a-n for obtaining a compressed neural network.

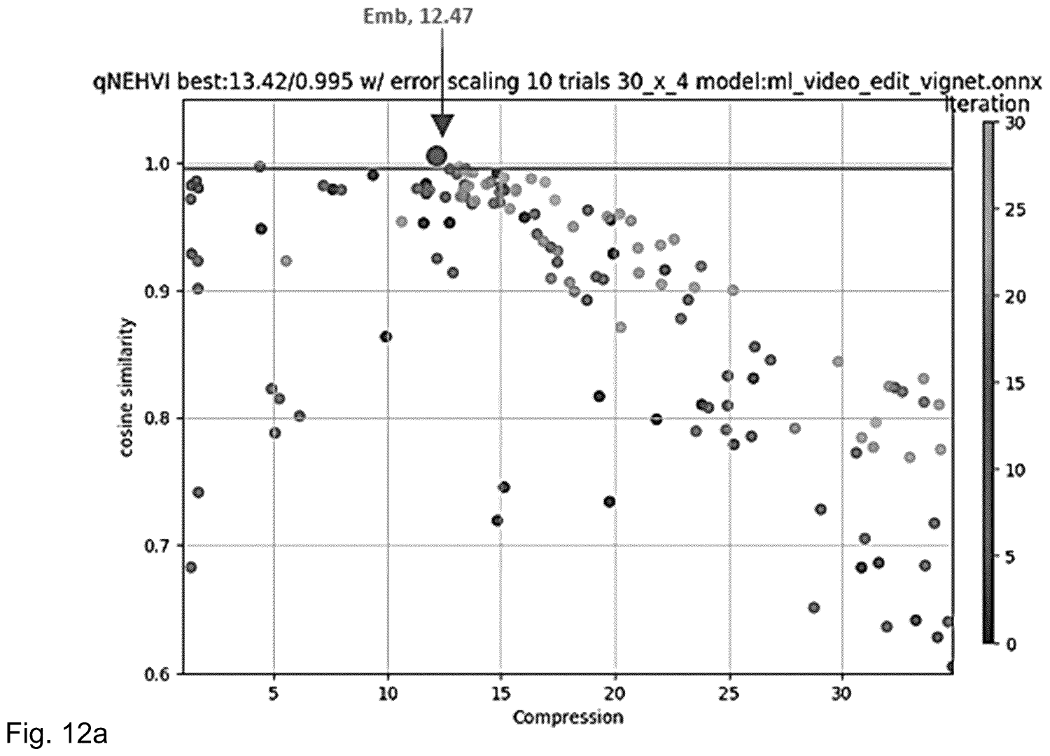

The compression performance provided by embodiments of the data processing apparatus 100 has been evaluated for various neural network models with different sizes using the cos distance criteria (wherein, by way of example, the quantization must reach a cosine similarity <0.005). As a baseline for comparison, a Mindspore version 1.6 converter has been used (tested on x86) which is already highly optimized compared to other current state-of-the-art solutions. As can be taken from the table shown in FIG. 11 the implementation provided by an embodiment of the data processing apparatus 100 converges fast even for large neural network models such as Resnet50 (in few seconds). The compression ratio provided by the embodiment of the data processing apparatus 100 is significant and superior, even to current state-of-the-art solution of Mindspore.

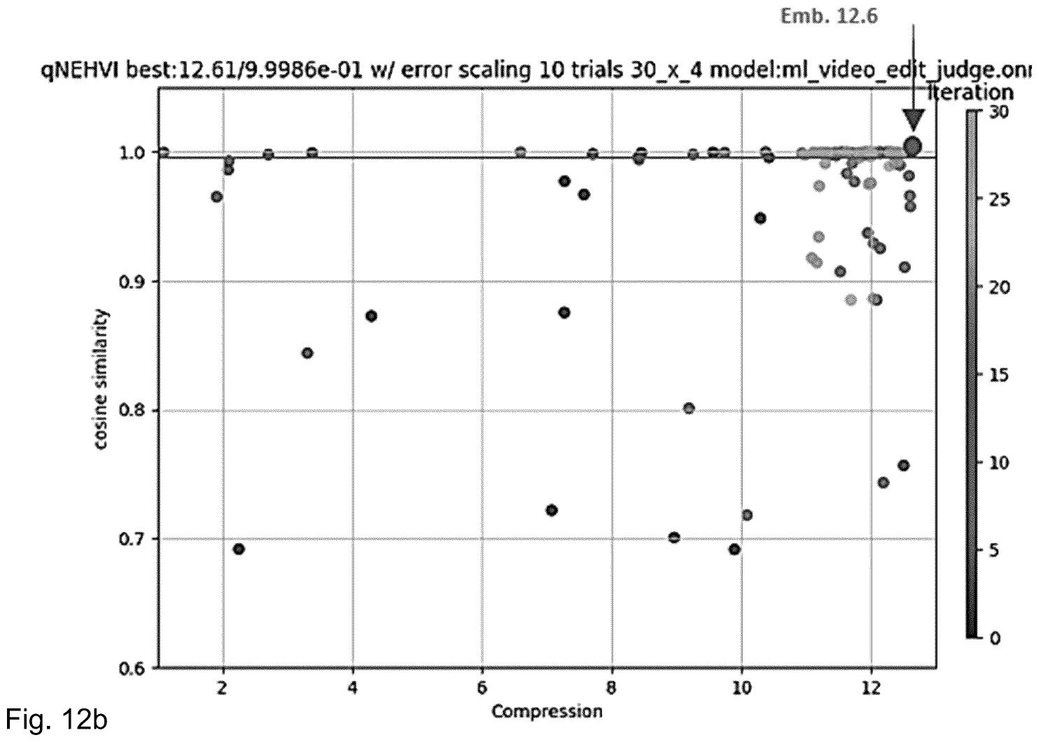

For assessing how far the solution provided by the data processing apparatus 100 according to an embodiment is from the actual optimal solution, the compression performance provided by the data processing apparatus 100 according to an embodiment was compared with compression performance provided by the Multi-Objective Bayesian Optimization (MOBO) solution, which is computationally very complex to obtain and takes long running times (few hours to days on multiple GPUs). As can be taken from FIGS. 12a, and 12b, the compression ratio achieved by the data processing apparatus 100 according to an embodiment is very similar to the compression ratio provided by the MOBO solution, obtained after running for a week.

The person skilled in the art will understand that the “blocks” (“units”) of the various figures (method and apparatus) represent or describe functionalities of embodiments of the present disclosure (rather than necessarily individual “units” in hardware or software) and thus describe equally functions or features of apparatus embodiments as well as method embodiments (unit=step).

In the several embodiments provided in the present application, it should be understood that the disclosed system, apparatus, and method may be implemented in other manners. For example, the described apparatus embodiment is merely exemplary. For example, the unit division is merely logical function division and may be other division in actual implementation.

For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or units may be implemented in electronic, mechanical, or other forms.

The units described as separate parts may or may not be physically separate, and parts displayed as units may or may not be physical units, may be located in one position, or may be distributed on a plurality of network units. Some or all of the units may be selected according to actual needs to achieve the objectives of the solutions of the embodiments.

In addition, functional units in the embodiments of the present disclosure may be integrated into one processing unit, or each of the units may exist alone physically, or two or more units are integrated into one unit.

1. A data processing apparatus, comprising:
a processing circuitry configured to:
operate a neural network comprising a plurality of processing layers, wherein each processing layer of the plurality of processing layers comprises a plurality of neural network weights;
compress the neural network by quantizing the plurality of neural network weights of each processing layer of the plurality of processing layers using a respective quantization bin size and by encoding the plurality of quantized neural network weights of each processing layer of the plurality of processing layers to obtain a compressed neural network; and
determine, for each processing layer of the plurality of processing layers, a norm based on the plurality of neural network weights of each processing layer of the plurality of processing layers, and determine the respective quantization bin size for each processing layer of the plurality of processing layers based on the norm of the processing layer.

2. The data processing apparatus of claim 1, wherein the processing circuitry is configured to determine, for each processing layer of the plurality of processing layers, the norm comprises the processing circuitry is configured to determine the norm of the respective processing layer based on the plurality of neural network weights of the respective processing layer as a square root of a sum of squares of the plurality of neural network weights of the respective processing layer.

3. The data processing apparatus of claim 1, wherein the processing circuitry is configured to determine the respective quantization bin size for each processing layer of the plurality of processing layers comprises the processing circuitry is configured to determine the respective quantization bin size for each processing layer of the plurality of processing layers based on the norm of the processing layer such that the respective quantization bin size is proportional to the norm of the processing layer.

4. The data processing apparatus of claim 3, wherein the processing circuitry is configured to determine the respective quantization bin size for each processing layer of the plurality of processing layers based on the norm of the processing layer comprises the processing circuitry is configured to determine the respective quantization bin size for each processing layer of the plurality of processing layers as a product of the norm of the processing layer and a proportionality constant, wherein the proportionality constant is the same for all of the plurality of processing layers.

5. The data processing apparatus of claim 4, wherein the processing circuitry is further configured to determine the proportionality constant based on a target quantization error.

6. The data processing apparatus of claim 5, wherein
the processing circuitry is further configured to determine a quantization error; and
the processing circuitry is configured to determine the proportionality constant comprises the processing circuitry is configured to determine the proportionality constant to be a largest proportionality constant, for which the quantization error is smaller than or equal to the target quantization error.

7. The data processing apparatus of claim 6, wherein the processing circuitry is configured to determine the proportionality constant further comprises the processing circuitry is configured to determine the proportionality constant using a giant-step baby-step scheme.

8. The data processing apparatus of claim 1, wherein the processing circuitry is configured to encode the plurality of quantized neural network weights of each processing layer of the plurality of processing layers to obtain the compressed neural network comprises the processing circuitry is configured to encode the plurality of quantized neural network weights of each processing layer of the plurality of processing layers using an entropy encoding scheme.

9. The data processing apparatus of claim 8, wherein the entropy encoding scheme is based on at least one of: a Huffman encoding scheme, an Arithmetic encoding scheme, or an Asymmetric Numeral Systems (ANS) encoding scheme.

10. The data processing apparatus of claim 1, wherein the data processing apparatus further comprises a volatile or non-volatile memory configured to store the compressed neural network.

11. The data processing apparatus of claim 9, wherein the processing circuitry is further configured to decompress the compressed neural network layer by layer.

12. The data processing apparatus of claim 1, wherein the processing circuitry is further configured to compress input data of the neural network.

13. The data processing apparatus of claim 1, wherein the plurality of processing layers comprises one or more sparse processing layers.

14. A computer-implemented method of data processing, comprising:
operating a neural network comprising a plurality of processing layers, wherein each processing layer of the plurality of processing layers comprises a plurality of neural network weights;
determining, for each processing layer of the plurality of processing layers, a norm based on the plurality of neural network weights of each processing layer of the plurality of processing layers;
determining a respective quantization bin size for each processing layer of the plurality of processing layers based on the norm of the processing layer; and
compressing the neural network by quantizing the plurality of neural network weights of each processing layer of the plurality of processing layers using the respective quantization bin size and by encoding the plurality of quantized neural network weights of each processing layer of the plurality of processing layers to obtain a compressed neural network.

15. The method of claim 14, wherein:
determining, for each processing layer of the plurality of processing layers, the norm comprises determining the norm of the respective processing layer based on the plurality of neural network weights of the respective processing layer as a square root of a sum of squares of the plurality of neural network weights of the respective processing layer.

16. The method of claim 14, wherein:
determining the respective quantization bin size for each processing layer of the plurality of processing layers comprises determining the respective quantization bin size for each processing layer of the plurality of processing layers based on the norm of the processing layer such that the respective quantization bin size is proportional to the norm of the processing layer.

17. The method of claim 16, wherein:
determining the respective quantization bin size for each processing layer of the plurality of processing layers based on the norm of the processing layer comprises determining the respective quantization bin size for each processing layer of the plurality of processing layers as a product of the norm of the processing layer and a proportionality constant, wherein the proportionality constant is the same for all of the plurality of processing layers.

18. The method of claim 17, further comprising:
determining the proportionality constant based on a target quantization error.

19. The method of claim 18, wherein:
the method further comprises determining a quantization error; and
determining the proportionality constant comprises determining the proportionality constant to be a largest proportionality constant, for which the quantization error is smaller than or equal to the target quantization error.

20. A computer program product comprising computer-executable instructions stored on a non-transitory computer-readable storage medium, the computer-executable instructions when executed by one or more processors of an apparatus, cause the apparatus to:
operate a neural network comprising a plurality of processing layers, wherein each processing layer of the plurality of processing layers comprises a plurality of neural network weights;
determine, for each processing layer of the plurality of processing layers, a norm based on the plurality of neural network weights of each processing layer of the plurality of processing layers;
determine a respective quantization bin size for each processing layer of the plurality of processing layers based on the norm of the processing layer; and
compress the neural network by quantizing the plurality of neural network weights of each processing layer of the plurality of processing layers using the respective quantization bin size and by encoding the plurality of quantized neural network weights of each processing layer of the plurality of processing layers to obtain a compressed neural network.
